(19) United States
(12) Patent Application Publication
(10) Pub. No.: US 2008/0186046 A1
(43) Pub. Date: Aug. 7, 2008

(54) Test socket for testing semiconductor chip, test apparatus including the test socket and method for testing semiconductor chip

(75) Inventors: Kum-Jin Yun, Cheonan-si (KR); Sang-Jin Kyung, Cheonan-si (KR); Hyun-Guen Iy, Cheonan-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/012,537

(22) Filed: Feb. 4, 2008

(30) Foreign Application Priority Data
Feb. 5, 2007 (KR) 10-2007-0011696

(51) Int. Cl. G01R 31/26

(52) U.S. Cl. 324/765

(57) ABSTRACT

A semiconductor package is tested while being inserted into a test socket installed at a test board. The test socket includes a base accommodating a semiconductor package and a contact sheet where a plurality of contact terminals are formed. The contact sheet is fixed to the base through an insert slot formed at one side of the base. The base includes an adaptor installed at a socket body fixed to a test board and fixing a contact sheet. The insert slot is formed between the top of the socket body and the bottom of the adaptor. The contact sheet has a plurality of fix holes. A plurality of stoppers are formed at a bottom surface of the adaptor and inserted into the fix holes, respectively. The adaptor exhibits the shape of a quadrangular ring. An inclined surface is formed at an inner wall of the adaptor to guide a position of the semiconductor package.

### CROSS-REFERENCE TO RELATED APPLICATIONS

This US non-provisional patent application claims priority under 35 U.S.C § 119 of Korean Patent Application 10-2007-0011696, filed in the Korean Intellectual Property Office on Feb. 5, 2007, the entirety of which is hereby incorporated by reference.

### BACKGROUND

The present invention relates to a test socket for testing a semiconductor package, a test apparatus including the test socket, and a method for testing a semiconductor package. More specifically, the present invention is directed to a test socket for testing electrical properties of a semiconductor package, a test apparatus including the test socket, and a method of testing a semiconductor package.

A wafer including a predetermined integrated circuit (IC) formed thereon is cut into a plurality of semiconductor chips and manufactured into a semiconductor package. A variety of tests are conducted to determine whether semiconductor packages are good or bad. The tests are performed repeatedly which is repeated to maintain reliability of products. One early stage defect test for semiconductor packages is called a burn-in test.

A burn-in test is conducted under conditions in which a thermal stress of a high temperature ranging from 80 to 125 degrees centigrade is applied to a semiconductor package. At this point, the semiconductor package operates at a high temperature under the state where a high electric field is applied thereto. During the burn-in test, short-lifespan packages do not withstand the test conditions, and defects are noted. Since semiconductor packages passing the burn-in test, i.e., normal semiconductor packages, indicate long lifespan, reliability of the system using the normal semiconductor packages may be enhanced.

The burn-in test is conducted under the conditions in which a semiconductor package is mounted in a test socket installed at a test board. Since 32 to 256 sockets are installed at one test board, a number of semiconductor packages may be collectively tested at the same time.

Conventional test sockets have been replaced according to a distance (e.g., ball pitch) between terminals of a semiconductor package. Since a terminal of a semiconductor package must be electrically connected to a socket pin provided at the contact board of a test socket to achieve the test for the semiconductor package, a distance between terminals must match a distance between socket pins. When a distance between terminals increases or decreases during the test for a semiconductor package where distances between terminals are different from each other, a conventional contact board cannot be used any longer. Therefore, it is necessary to replace the conventional contact board with a new one.

In order to replace a contact board with a new one, a test socket must first be detached from a test board. The replacement of the contact board incurs time and effort.

### SUMMARY OF THE INVENTION

According to one aspect, the present invention is directed to a test socket at a test board for testing performance of a semiconductor package. In an exemplary embodiment, the test socket may include: a base accommodating the semiconductor package; and a contact sheet at which are formed a plurality of contact terminals each being in contact with a plurality of terminals formed at the semiconductor package, the contact sheet being fixed to the base.

In one embodiment, an insert slot is formed at one side of the base and acts as an entrance through which the contact sheet enters or exits.

In one embodiment, the base comprises a body fixed to the test board and an adaptor coupled with the top of the body to fix the contact sheet. The insert slot is formed between the body and the adaptor.

In one embodiment, a plurality of fix holes are formed at the contact sheet. A plurality of stoppers are formed at a bottom surface of the adaptor and inserted into the fix holes, respectively.

In one embodiment, the adaptor has the shape of a quadrangular ring, and an inclined surface is formed at an inner wall of the adaptor to guide a position of the semiconductor package.

In one embodiment, the test socket further comprises a latch provided to fasten the semiconductor package accommodated at the base and a latch driving member provided to drive the latch.

In one embodiment, the latch driving member comprises a cover coupled with the top of the base and moving up and down to drive the latch and an elastic member provided between the cover and the body and applying an elastic force against the cover.

According to another aspect, the invention is directed to an apparatus for testing a semiconductor package. In an exemplary embodiment, the apparatus may include: a test socket at a test board for testing performance of the semiconductor package; a pick-and-place tool provided to carry the semiconductor package and load/unload the carried semiconductor package in/from the test socket; and a head assembly disposed between the pick-and-place tool and the test socket and guiding a position of the semiconductor package loaded in the test socket. The test socket comprises: a base accommodating the semiconductor package; and a contact sheet at which are formed a plurality of contact terminals each being in contact with a plurality of terminals formed at the semiconductor package, the contact sheet being fixed to the base.

In one embodiment, an insert slot is formed at one side of the base and acts as an entrance through which the contact sheet enters or exits.

In one embodiment, the base comprises a body fixed to the test board and an adaptor installed at the body to fix the contact sheet. The insert slot is formed between the body and the adaptor.

In one embodiment, a plurality of fix holes are formed at the contact sheet. A plurality of stoppers are formed at a bottom surface of the adaptor and inserted into the fix holes, respectively.

According to another aspect, the present invention is directed to a method of testing performance of a semiconductor package. In an exemplary embodiment, the method may include: selecting a contact sheet corresponding to the semiconductor package; fixing the contact sheet to a base accommodating the semiconductor package; and installing the semiconductor package at the base.

In one embodiment, the contact sheet is fixed to the base through an insert slot formed at one side of the base.

In one embodiment, the base comprises a body and an adaptor installed at the body to fix the contact sheet. The insert slot is formed between the body and the adaptor.

In one embodiment, installing the semiconductor package at the base comprises guiding a position of the semiconductor package by an inclined surface formed at an inner wall of the adaptor.

In one embodiment, installing the semiconductor package at the base comprises: carrying the semiconductor package onto the base by means of a pick-and-place tool provided over the base; dropping the semiconductor package toward the base; and guiding a position of the dropped semiconductor package by means of a head assembly positioned between the pick-and-place tool and the base.

In one embodiment, the base comprises: a body fixed to the test board; and an adaptor installed at the body to fix the contact sheet. Fixing the contact sheet to the base comprises: fixing the contact sheet to a bottom surface of the adaptor; and fixing the adaptor to the body through the top of the body.

In one embodiment, fixing the contact sheet to a base accommodating the semiconductor package is done while the base is installed at a test board.

10.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views.

The drawings are not necessarily to scale, emphasis instead being placed upon illustrating the principles of the invention.

FIG. 1 is a cross-sectional view of a burn-in test apparatus.

FIG. 2 is a perspective view of a test socket according to the present invention.

FIG. 3 is a top plan view of the test socket of FIG. 2.

FIG. 4 is a cross-sectional view taken along a line I-I′ of FIG. 2.

FIG. 5 is a cross-sectional view taken along a line II-II′ of FIG. 3.

FIG. 6 is an exploded perspective view of an adaptor and a contact sheet according to the invention.

FIG. 7 illustrates a contact sheet is inserted into an insert slot according to the invention.

FIG. 8 illustrates an adaptor coupled with a body while a contact sheet is coupled with the adaptor according to the invention.

FIG. 9 illustrates a semiconductor package loaded on a contact sheet by means of an adaptor according to the invention.

FIG. 10 and FIG. 11 illustrate a semiconductor package fixed by means of a latch illustrated in FIG. 2 according to the invention.

FIG. 12 illustrates an alternative adaptor according to the present invention.

FIG. 13 is a perspective view of a head assembly of a test apparatus according to the present invention.

FIG. 14 is a top plan view of the head assembly of FIG. 13.

FIG. 15 is a front view of the head assembly of FIG. 13.

FIG. 16 is a perspective view of a unit head assembly illustrated in FIG. 13.

FIG. 17 is a reverse perspective view of a unit head assembly illustrated in FIG. 13.

FIG. 18 illustrates a semiconductor package loaded by means of a head assembly illustrated in FIG. 13.

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art.

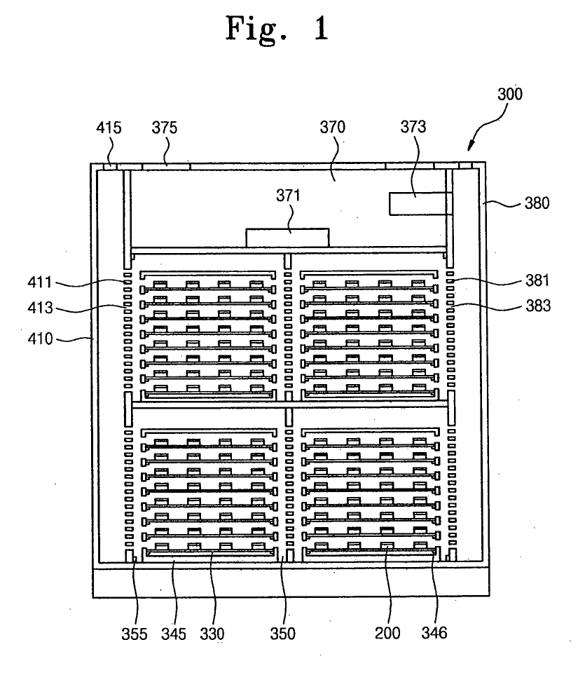

Referring to FIG. 1, a burn-in test apparatus 300 is a monitoring burn-in test apparatus configured to perform a burn-in test for a semiconductor package 10. The burn-in test apparatus 300 adjusts a test temperature condition using heated air.

The burn-in test apparatus 300 includes a burn-in chamber 350 sealed from the outside, a heating part 370 heating air to adjust test conditions, an air supply duct 380 to supply heated air into the burn-in chamber 350, and an exhaust duct 410 to exhaust the air of the burn-in chamber 350 to the outside.

A test for the semiconductor package 10 is performed under the state where the semiconductor package 10 is loaded inside the burn-in chamber 350. A temperature sensor 355 is installed inside the burn-in chamber 350 to measure an internal temperature. One or more semiconductor packages 10 are mounted on one or more test sockets 200, and a plurality of test sockets 200 are each installed at a burn-in board 330. A plurality of burn-in boards 330 are installed inside the burn-in chamber 350 where they are subjected to a test. The burn-in board 330 is installed at a rack 345 where a guide rail 346 is provided. A plurality of racks 345 are installed inside the burn-in chamber 350. In this embodiment, four racks 345 are inside the burn-in chamber 350.

The heating part 370 is disposed over the burn-in chamber 350 and is configured to generate heated air supplied into the burn-in chamber 350. The heating part 370 includes a heater 371 to heat air and a fan 373 to forcibly blow heated air to an air supply duct 380.

The air supply duct 380 provides a flow path along which the heated air is supplied into the burn-in chamber 350 from the heating part 370. The exhaust duct 410 provides a flow path along which air is exhausted to the outside from the burn-in chamber 350. The air supply duct 380 and the exhaust duct 410 are installed at both sides of the burn-in chamber 350, respectively. The air supply duct 380 is installed adjacent to the burn-in chamber 350 and receives air from the heating part 370. The exhaust duct 410 is installed adjacent to the burn-in chamber 350 and exhausts air from the burn-in chamber 350. The air supply duct 380 and the burn-in chamber 350 are separated by a deflection plate 381, and the exhaust duct 410 and the burn-in chamber 350 are separated by a deflection plate 411. These deflection plates 381 and 411 have holes 383 and 413 formed in a certain direction, respectively. The air is supplied and exhausted through the holes 381 and 411.

Controlling a temperature of the burn-in chamber 350 will now be described in detail. An internal temperature of the burn-in chamber 350 is raised until it reaches a preset temperature. The air flowing in through an inlet port 375 is heated by the heater 371 and supplied to the air supply duct 380 by the fan 373. The air supplied to the air supply duct 380 is supplied into the burn-in chamber through the deflection plate 381. If a temperature measured by the temperature sensor 355 reaches the preset temperature, an operation of the heater 371 is paused and the fan 373 continues to operate. If the internal temperature of the burn-in chamber 350 increases over the preset temperature due to the heat generated by the operation of the semiconductor package 10, the air inside the burn-in chamber 350 is exhausted to an exhaust port 415 through the exhaust duct 410. On the other hand, if the internal temperature of the burn-in chamber 350 decreases below the preset temperature, the heater 371 re-operates to heat air supplied into the burn-in chamber 350. These steps are repeated to allow the internal temperature of the burn-chamber to be maintained at the preset temperature. Under this state, an electrical test is conducted by means of a system part (not shown).

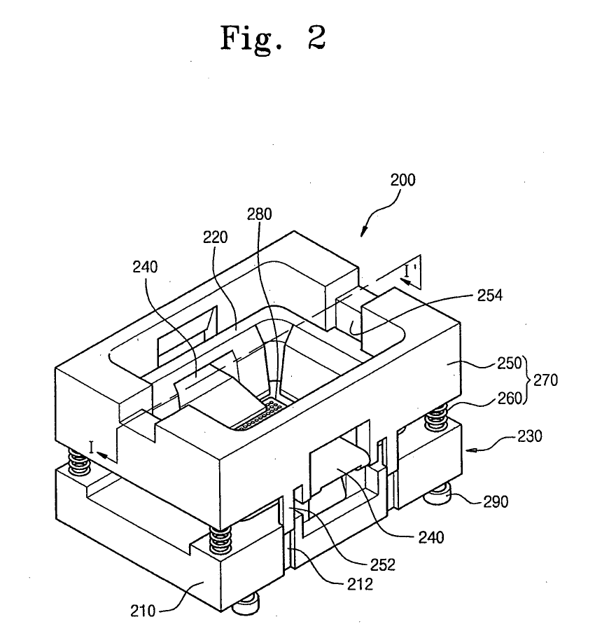

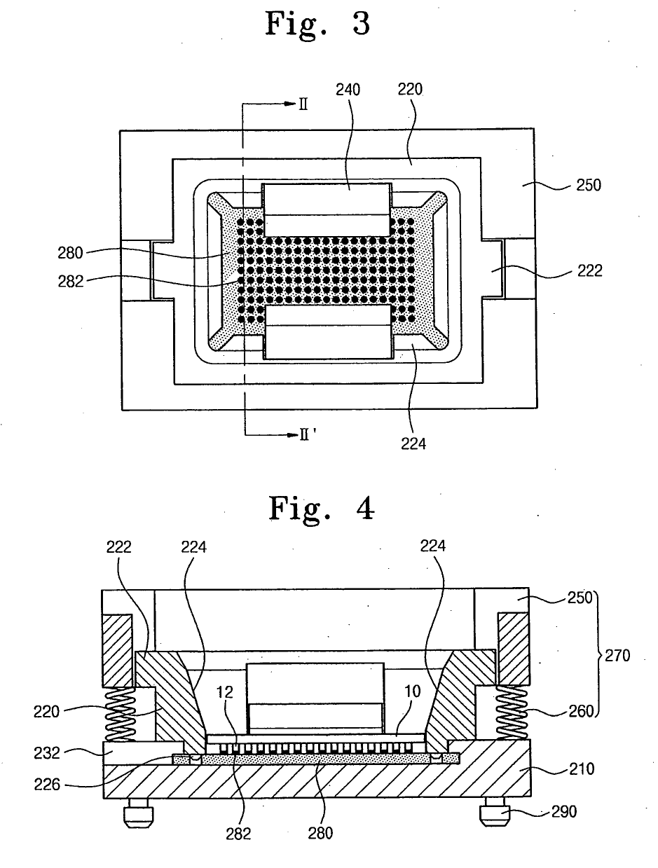

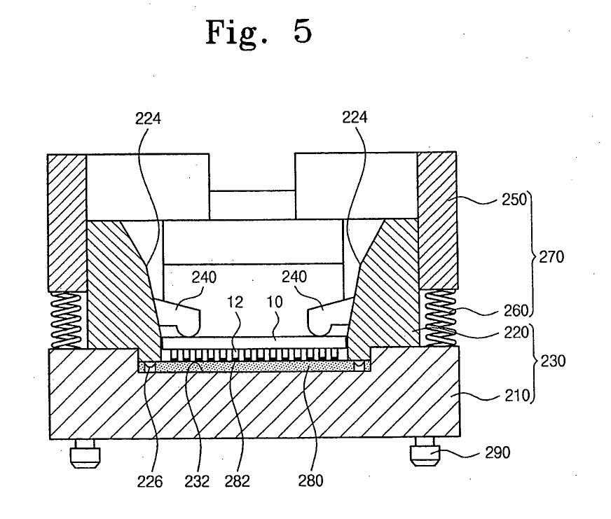

FIG. 2 is a perspective view of a test socket 200 according to the present invention, and FIG. 3 is a top plan view of the test socket 200 of FIG. 2. FIGS. 4 and 5 are cross-sectional views taken along lines I-I′ and II-II′ of FIG. 3, respectively.

As described above, a plurality of test sockets 200 are each installed at a burn-in board 330. A semiconductor package 200 is mounted on a test socket 200. Under this state, a test is conducted for the semiconductor package 10.

The test socket 200 includes a base 230 and a contact sheet 280 fixed to the base 230. The base 230 includes a body 210 and an adaptor 220 and accommodates the semiconductor package 10. A support 290 is coupled to the bottom of the body 210. The body 210 is fixed to a burn-in board 330 by means of the support 290. As illustrated in FIG. 2, a plurality of guide grooves 212 are formed at both side portions of the body 210 and serve to guide the movement of guide bars 252, which will be described below, respectively.

Referring to FIG. 3, an adaptor 220 has the shape of a quadrangular ring and is coupled with the top of the body 210. A guide rail 222 is provided at both sides of an outer wall of the adaptor 220 and migrates along a guide groove 254 provided at a cover 250 which will be described below. As illustrated in FIGS. 4 and 5, an inclined surface 224 is formed at the inner wall of the adaptor 220. The inclined surface 224 protrudes downwardly toward the center of the adaptor 220. The inclined surface 224 is formed at respective four sides, guiding the semiconductor package 10 to be loaded at a desired position on the base 230. The edge of the semiconductor package loaded at the desired position on the base 230 is in contact with the bottom ends of the inclined surfaces 224. When a size of the semiconductor package 10 varies, the adaptor 220 must change.

A plurality of stoppers 226 are provided at the bottom surface of the adaptor 220 disposed on an insert slot 232. A stopper 226 serves to fix a contact sheet 280 installed on the insert slot 232. A plurality of fix holes 284 are formed on the contact sheet 280. When the contact sheet 280 is inserted on the insert slot 232, the stoppers 226 are inserted into the fix holes 284, respectively. Thus, the contact sheet 280 may be fixed on the insert slot 232.

Referring to FIG. 5, an insert slot 232 is formed between a body 210 and an adaptor 220. A contact sheet 280 is installed on the insert slot 232. As illustrated in FIG. 4, an inlet is formed at one side of the insert slot 232. The contact sheet 280 is inserted into the insert slot 232 through the inlet of the insert slot 232, which will be described in detail later.

The contact sheet 280 is made of the same material as a flexible circuit board, and a plurality of contact terminals 282 are formed on the contact sheet 280. As illustrated in FIG. 5, a semiconductor package 10 to be tested is loaded on the contact sheet 280, and the contact terminals 282 are in contact with terminals 12 formed at the semiconductor package 10. Thus, the semiconductor package is electrically connected to the contact sheet 280. The contact sheet 280 may change whenever there is variation in size or terminal-to-terminal distance (e.g., ball pitch) of a semiconductor package 10 to be tested. As stated previously, the semiconductor package 10 and the contact sheet 280 are electrically connected by contacting the contact terminals 282 with the terminals 12. For this reason, if a distance between the terminals 12 changes, a distance between the contact terminals 282 must also change. While this embodiment specifies that the contact sheet 280 is made of the same material as a flexible circuit board, the present invention is not limited to that material. The contact sheet 280 can include a printed circuit board (PCB).

The test socket 200 further includes a latch 240 and a latch driving member 270. The latch 240 fixes a position of the semiconductor package 10 in the base 230, and the latch driving member 270 drives the latch 240.

As illustrated in FIG. 5, the latch 240 applies a pressure to a top surface of the semiconductor package 10 in the base 230 to hold the semiconductor package 10 and prevents the semiconductor package 10 from moving. The latch 240 is rotatable by means of the latch driving member 270 and rotates to hold/unhold the semiconductor package 10. The latch driving member 270 includes a cover 250 and a spring 260. The cover 250 has the shape of a quadrangular ring to surround the adapter 220. Guide bars 252 are provided at both sides of the cover 250 and move along guide grooves 212, respectively. The spring is installed between the cover 250 and the body 210 and provides an elastic force upwardly against the cover 250. Driving the latch 240 will be described in detail below.

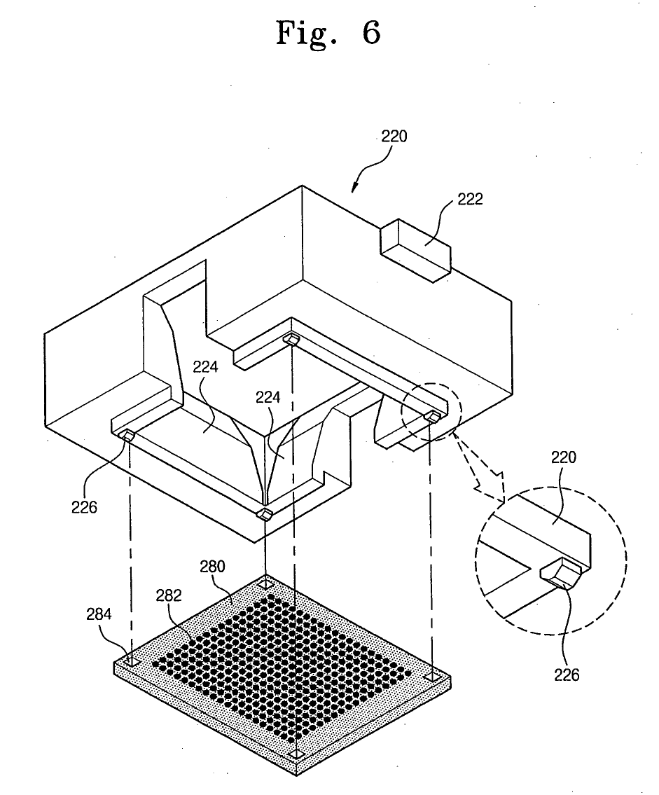

FIG. 6 is an exploded perspective view of the adapter 220 and the contact sheet 280 illustrated in FIG. 2.

As described above, a plurality of stoppers 226 are provided at the bottom surface of the adaptor 220 corresponding to the insert slot 232. The stoppers 226 fix the contact sheet 280 installed on the insert slot 232. A plurality of fix holes 284 are formed on the contact sheet 280. When the contact sheet is inserted on the insert slot 232, the stoppers 226 are inserted into respective fix holes 284. Thus, the contact sheet 280 may be fixed on the insert slot 232. Since an inclined surface is formed at the top surface of the stopper 226 as illustrated in FIG. 6, the contact sheet 280 may be fixed on the insert slot 232 by the inclined surface. This will be described in detail below. A plurality of contact terminals 282 are provided at one surface of the contact sheet 280 facing the adaptor 220. Fix holes 284 are formed at the corners of the contact sheet 280 to face the stoppers 226.

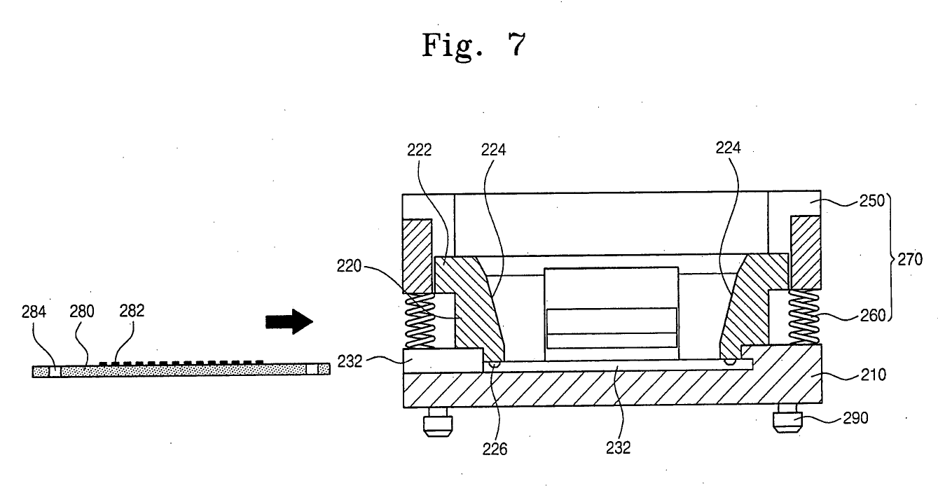

FIG. 7 illustrates that the contact sheet 280 is inserted into the insert slot 232 illustrated in FIG. 4. As described above, an inlet is formed at one side of the insert slot 232, and the contact sheet 280 is inserted into the insert slot 232 through the inlet. The contact sheet 280 is inserted to the right through the insert slot 232. The stoppers 226 provided over the insert slot 232 are inserted into the fix holes 284 formed at the contact sheet 280, respectively. Thus, the contact sheet 280 is inserted into the insert slot 232.

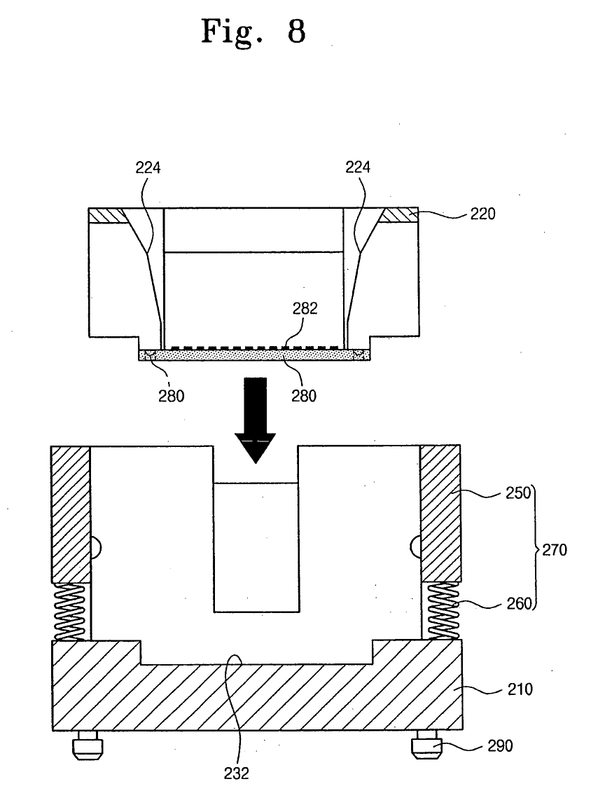

FIG. 8 illustrates that an adaptor 220 is coupled with a body 210 while a contact sheet 280 is coupled with the adaptor 220 illustrated in FIG. 6. Although FIG. 7 illustrates that the contact sheet 280 is installed at the bottom of the adaptor 220 through the insert slot 232, the adaptor 220 may be coupled with a body 210 while the contact sheet 280 is coupled with the adaptor 220 illustrated in FIG. 6. Specifically, as illustrated in FIG. 8, the adaptor 220 may be coupled with the top of the body 210 through the open top of the cover 250 while the contact sheet 280 is coupled with the bottom of the adaptor 220.

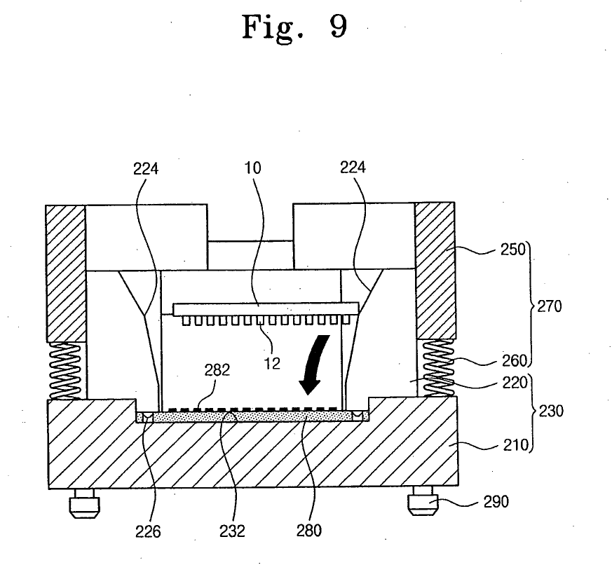

FIG. 9 illustrates that a semiconductor package 10 is loaded on the contact sheet 280 by means of the adaptor illustrated in FIG. 5. As described above, an inclined surface 224 is formed at the inner wall of the adaptor 220 to protrude downwardly toward the center of the adaptor 220. The inclined surface 224 guides the semiconductor package 10 such that the semiconductor package 10 is loaded at the desired position on a base 230. The edge of the semiconductor package 10 falling from the top of the adaptor 220 may move downwardly along the inclined surface 224 to be loaded at a desired position on the base 230. The edge of the semiconductor package 10 loaded at the desired position on the base 230 is in contact with the bottom edge of each inclined surface 224.

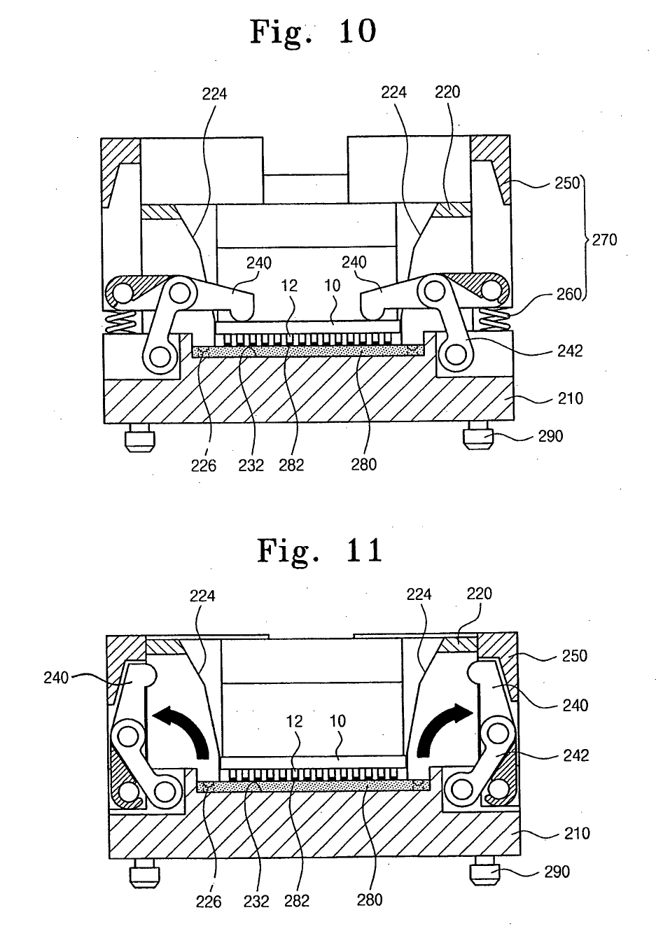

FIG. 10 and FIG. 11 illustrate that a semiconductor package 10 is fixed by means of the latch 240 illustrated in FIG. 2.

The latch 240 rotates by elevation of a cover 250. As illustrated, one end of the latch 240 is hingedly coupled with the cover 250, and a central portion of the latch 240 engages with an auxiliary link 242 that is hingedly coupled with the body 210. Similarly, the auxiliary link 242 is hingedly coupled with the central portion of the latch 240. Thus, as shown in FIG. 10, if the cover 250 is elevated, the latch 240 is placed on the semiconductor package 10 by a link movement and holds the semiconductor package 10. As shown in FIG. 11, if the cover 250 is lowered, the latch 240 is removed from the top of the semiconductor package 10 while rotating in an arrow direction and unholds the semiconductor package 10. When the latch 240 is in an “unhold” state, the semiconductor package 10 is loaded/unloaded on/from the top surface of the base 230.

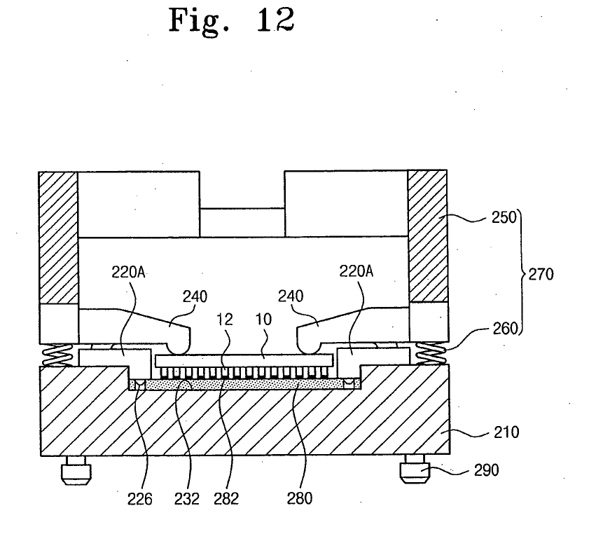

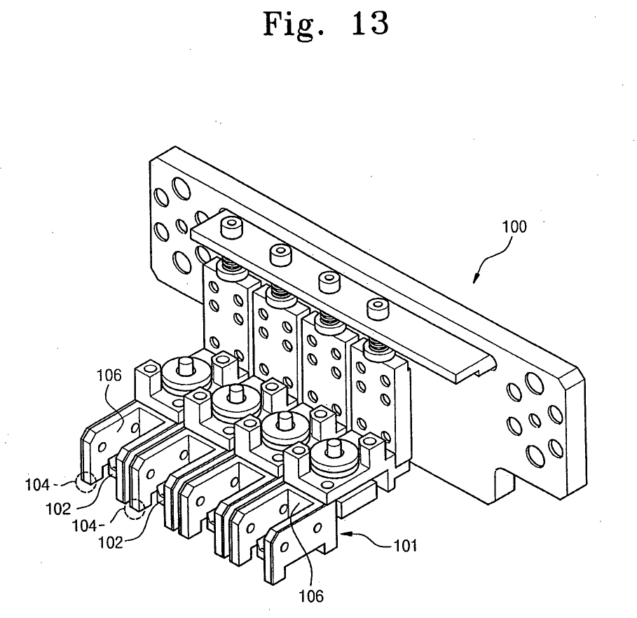

FIG. 12 illustrates an alternative adaptor 220A according to the present invention. Unlike the case of the above-described adaptor 220, an inclined surface is not formed at the adaptor 220A. Thus, the adaptor 220A may not align the semiconductor package 10 at an accurate position. Instead, the position of the semiconductor package 10 is aligned using a head assembly 100 illustrated in FIGS. 13 through 18.

Except for the inclined surface 224, the alternative adaptor 220A is substantially identical to the above-described adaptor 220. Therefore, description of the adaptor will not be repeated.

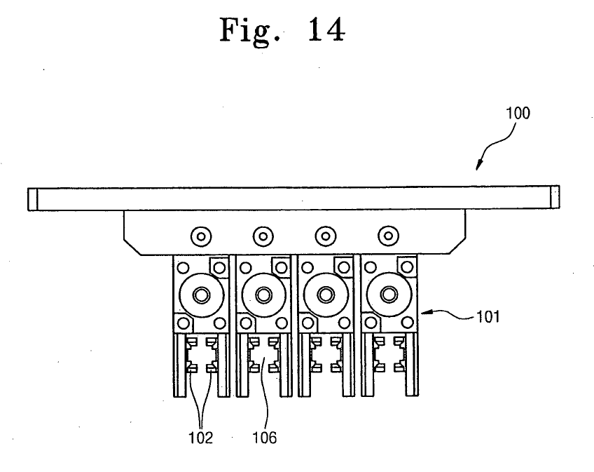

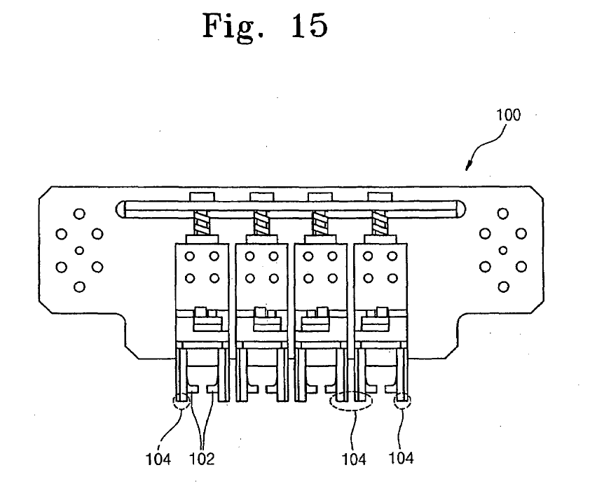

FIG. 13 is a perspective view of a head assembly 100 of a test apparatus 300 according to the present invention. FIG. 14 is a top plan view of the head assembly 100 of FIG. 13, and FIG. 15 is a front view of the head assembly 100 of FIG. 13.

As illustrated in FIGS. 13, 14, and 15, the head assembly 100 performs an aligning operation done by the inclined surface 224 of the adaptor 220A described in the foregoing embodiment.

This embodiment is concerned with a burn-in test and a parallel test which are conducted to test a plurality of semiconductor packages 10 at the same time. Accordingly, a plurality of semiconductor packages are loaded or unloaded not one after another but at the same time. The head assembly 100 includes four unit head assemblies 101.

The head assembly 100 includes a pick-and-place tool operation unit 106 defining an operation space of a pick-and-place tool (400 of FIG. 4) used to load or unload a semiconductor package 10. Also the head assembly 100 includes a package guider 102 and a socket guider 104.

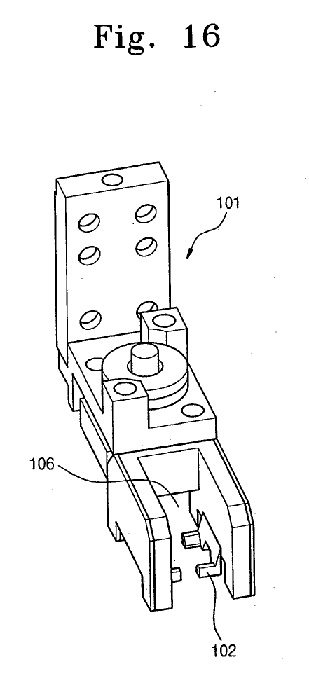

FIG. 16 is a perspective view of a unit head assembly 100 illustrated in FIG. 13. Referring to FIG. 16, the package guider 102 is provided at the bottom of the pick-and-place tool operation unit 106 and aligns a semiconductor package 10 using an inclined surface, which is similar to the inclined surface 224 of the adaptor 220, when the semiconductor package 10 is loaded within a base 230. Thus, if the size of a semiconductor package 10 changes, the package guider 102 of the unit head assembly 101 must be replaced.

A minimum of 32 and a maximum of 256 test sockets are installed on a typical burn-in board 330, and a number of burn-in boards 330 are used for a particular type of semiconductor package 10. Therefore, considerable cost and time are required to replace an adaptor 220 by hand. However, according to this embodiment, the same effect may be achieved only by replacing, for example, four, package guiders 102.

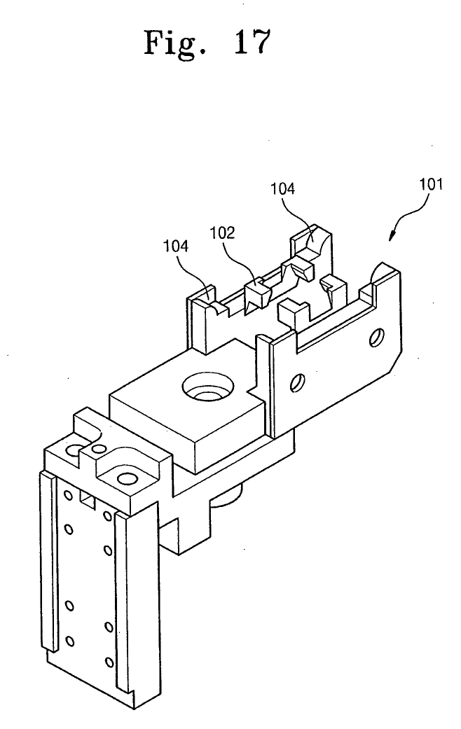

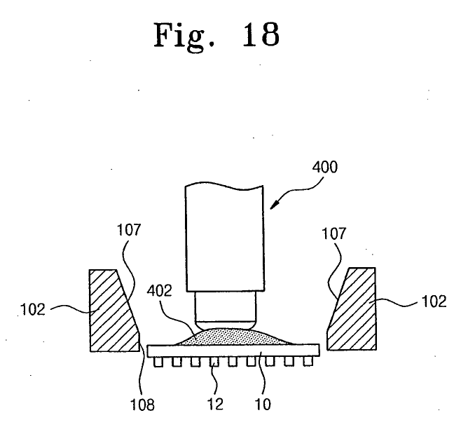

FIG. 17 is a reverse perspective view of FIG. 13. If the package guider 102 is misaligned when a head assembly 101 comes in contact with a cover 250, it is difficult to normally connect a terminal 12 of the semiconductor package 10 to a contact terminal 282 of a contact sheet 280 although the package guider 102 operates normally. In order to overcome the above disadvantage, an inclined surface is provided at the end of a socket guider 104 and the socket guider 104 slides along the inclined surface to be aligned with four corners of the cover 250. Accordingly, the positions of the head assembly 101 and the cover 250 are accurately aligned before the package guider 102 operates.

FIG. 18 illustrates that a semiconductor package 10 is loaded by means of the head assembly 100 illustrated in FIG. 13.

As illustrated in FIG. 18, a typical pick-and-place tool 400 includes a vacuum adsorption unit 402, which adsorbs a semiconductor package 10 under vacuum and moves the adsorbed semiconductor package 10. If the vacuum of the adsorption unit 402 is released, the semiconductor package 10 is removed from the vacuum adsorption unit 402 to be loaded within a base 230. Since an inclined unit 107 is disposed at the package guider 102, the semiconductor package 10 passing the inclined unit 107 is correctly aligned to drop and be accurately loaded at a desired position within the base 230 even when there is an error of a loading position of the pick-and-place tool 400.

As described above, although a distance between terminals of a semiconductor package 10 changes, the semiconductor package 10 may be tested without replacement of a test socket 200 by replacing only a contact sheet 280. Further, it is unnecessary to remove the test socket 200 from a burn-in board 330. Further, a changed semiconductor package 10 may be tested by replacing only a contact sheet 280. Further, replacement of the contact sheet 280 may be done easily.

According to the present invention, when a ball pitch of a semiconductor package changes, time and effort required to replace a test socket are reduced. Moreover, semiconductor packages having various ball pitches are easily tested.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A test socket at a test board for testing performance of a semiconductor package, the test socket comprising:
a base accommodating the semiconductor package; and
a contact sheet at which are formed a plurality of contact terminals each being in contact with a plurality of terminals formed at the semiconductor package, the contact sheet being fixed to the base.

2. The test socket as set forth in claim 1, wherein an insert slot is formed at one side of the base and acts as an entrance through which the contact sheet enters or exits.

3. The test socket as set forth in claim 2, wherein the base comprises:
a body fixed to the test board; and
an adaptor coupled with the top of the body to fix the contact sheet,
wherein the insert slot is formed between the body and the adaptor.

4. The test socket as set forth in claim 3, wherein a plurality of fix holes are formed at the contact sheet, and
wherein a plurality of stoppers are formed at a bottom surface of the adaptor and inserted into the fix holes, respectively.

5. The test socket as set forth in claim 3, wherein the adaptor has the shape of a quadrangular ring, and an inclined surface is formed at an inner wall of the adaptor to guide a position of the semiconductor package.

6. The test socket as set forth in claim 1, further comprising:
a latch provided to fasten the semiconductor package accommodated at the base; and
a latch driving member provided to drive the latch.

7. The test socket as set forth in claim 6, wherein the latch driving member comprises:
a cover coupled with the top of the base and moving up and down to drive the latch; and
an elastic member provided between the cover and the body and applying an elastic force against the cover.

8. The test socket as set forth in claim 1, wherein the base comprises:
a body fixed to the test body; and
an adaptor installed at the body to fix the contact sheet,
wherein a plurality of fix holes are formed at the contact sheet, and
wherein a plurality of stoppers are formed at a bottom surface of the adaptor and inserted into the fix holes, respectively.

9. The test socket as set forth in claim 8, wherein the adaptor has the shape of a quadrangular ring, and an inclined surface is formed at an inner wall of the adaptor to guide a position of the semiconductor package.

10. An apparatus of testing a semiconductor package, comprising:
a test socket at a test board for testing performance of the semiconductor package;
a pick-and-place tool provided to carry the semiconductor package and load/unload the carried semiconductor package in/from the test socket; and
a head assembly disposed between the pick-and-place tool and the test socket and guiding a position of the semiconductor package loaded in the test socket,
wherein the test stock comprises:
a base accommodating the semiconductor package; and
a contact sheet at which are formed a plurality of contact terminals each being in contact with a plurality of terminals formed at the semiconductor package, the contact sheet being fixed to the base.

11. The apparatus as set forth in claim 10, wherein an insert slot is formed at one side of the base and acts as an entrance through which the contact sheet enters or exits.

12. The apparatus as set forth in claim 11, wherein the base comprises:
a body fixed to the test board; and
an adaptor installed at the body to fix the contact sheet,
wherein the insert slot is formed between the body and the adaptor.

13. The apparatus as set forth in claim 12, wherein a plurality of fix holes are formed at the contact sheet, and
wherein a plurality of stoppers are formed at a bottom surface of the adaptor and inserted into the fix holes, respectively.

14. The apparatus as set forth in claim 10, wherein the base comprises:
a body fixed to the test body; and
an adaptor installed at the body to fix the contact sheet,
wherein a plurality of fix holes are formed at the contact sheet, and
wherein a plurality of stoppers are formed at a bottom surface of the adaptor and inserted into the fix holes, respectively.

15. A method of testing performance of a semiconductor package, comprising:
selecting a contact sheet corresponding to the semiconductor package;
fixing the contact sheet to a base accommodating the semiconductor package; and
installing the semiconductor package at the base.

16. The method as set forth in claim 15, wherein the contact sheet is fixed to the base through an insert slot formed at one side of the base.

17. The method as set forth in claim 16, wherein the base comprises:
a body; and
an adaptor installed at the body to fix the contact sheet,
wherein the insert slot is formed between the body and the adaptor.

18. The method as set forth in claim 15, wherein installing the semiconductor package at the base comprises:
guiding a position of the semiconductor package by an inclined surface formed at an inner wall of the adaptor.

19. The method as set forth in claim 15, wherein installing the semiconductor package at the base comprises:
carrying the semiconductor package onto the base by means of a pick-and-place tool provided over the base;
dropping the semiconductor package toward the base; and
guiding a position of the dropped semiconductor package by means of a head assembly positioned between the pick-and-place tool and the base.

20. The method as set forth in claim 15, wherein the base comprises:
a body fixed to the test board; and
an adaptor installed at the body to fix the contact sheet,
wherein fixing the contact sheet to the base comprises:
fixing the contact sheet to a bottom surface of the adaptor; and
fixing the adaptor to the body through the top of the body.
